(19) United States
(12) Patent Application Publication
(10) Pub. No.: US 2025/0147528 A1
(43) Pub. Date: May 8, 2025

(54) ELECTRONIC DEVICE

(71) Applicant: STMicroelectronics International N.V., Geneva (CH)

(72) Inventor: Jimmy Fort, Puyloubier (FR)

(21) Appl. No.: 18/934,832

(22) Filed: Nov. 1, 2024

(30) Foreign Application Priority Data
Nov. 3, 2023 (FR) 2311974

(51) Int. Cl. G05F 1/56

(52) U.S. Cl. CPC G05F 1/56

(57) ABSTRACT

The present description concerns a device comprising a voltage regulator comprising first and second branches comprising first, second, and third transistors, the control nodes of the first transistors of the first and second branches being coupled together, the control node of the third transistor of each first and second branch being coupled to the junction point of the first and second transistors of the same branch, a fourth transistor, and a fifth transistor, the control nodes of the fourth transistor and of the second transistor of the first branch being coupled together to a node of application of a set point voltage, the control nodes of the fifth transistor and of the second transistor of the second branch being coupled together to an output node of the regulator.

### CROSS REFERENCED TO RELATED APPLICATIONS

The present disclosure is based on, and claims the priority of French Patent Application No. 2311974, filed on Nov. 3, 2023 and entitled “dispositif électronique” (electronic device), the content of which is hereby incorporated herein by reference.

### TECHNICAL FIELD

The present disclosure generally concerns electronic devices and more particularly electronic devices comprising voltage regulators.

### BACKGROUND

A voltage regulator is an electronic component configured to keep a substantially constant voltage at its output. Voltage regulators may for example be linear regulators, that is, regulators based on an active component working in its linear area, or on a passive component, such as a Zener diode, working in its reverse area.

One type of linear regulators corresponds to so-called low drop-out (LDO) regulators. Regulators of this type are such that the output voltage is very close to the power supply voltage of the regulator.

### SUMMARY

An embodiment provides a device comprising a voltage regulator, the regulator comprising: first and second branches, each first and second branch comprising first, second, and third transistors coupled in series, in this order, between a first node of application of a power supply voltage and a second node of application of a reference voltage, the control nodes of the first transistors of the first and second branches being coupled together, the control node of the third transistor of each first and second branch being coupled to the junction point of the first and second transistors of the same branch; a fourth transistor coupled between the junction point of the second and third transistors of the second branch and a third node; and a fifth transistor coupled between the junction point of the second and third transistors of the first branch and a fourth node, the control nodes of the fourth transistor and of the second transistor of the first branch being coupled together to a node of application of a set point voltage, the control nodes of the fifth transistor and of the second transistor of the second branch being coupled together to an output node of the regulator.

According to an embodiment, the first transistors of the first and second branches are P-channel MOSFET transistors, and the second and third transistors of the first and second branches are N-channel MOSFET transistors.

According to an embodiment, the regulator comprises, coupled in this order in series between the first and second nodes, sixth and seventh transistors, a first resistor, and eighth and ninth transistors, the control node of the sixth transistor being coupled to the junction point of the seventh transistor and of the resistor, the control node of the sixth transistor being further coupled to the control nodes of the first transistors of the first and second branches, the control node of the seventh transistor being coupled to the junction point of the transistor and of the resistor.

According to an embodiment, the regulator comprises, coupled in this order in series between the first and second nodes, a current source, a second resistor, and tenth and eleventh transistors, the control node of the tenth transistor being coupled to the junction point of the second resistor and of the current source and to the control node of the eighth transistor, the control node of the eleventh transistor being coupled to the control node of the ninth transistor.

According to an embodiment, the regulator comprises twelfth, thirteenth, and fourteenth transistors coupled, in this order, in series between the first and second nodes, a control node of the fourteenth transistor being coupled to the control node of the third transistor of the first branch, a control node of the thirteenth transistor being coupled to the control node of the eighth transistor.

According to an embodiment, the regulator comprises fifteenth, sixteenth, and seventeenth transistors coupled, in this order, in series between the first and second nodes, a control node of the seventeenth transistor being coupled to the control node of the third transistor of the second branch, a control node of the sixteenth transistor being coupled to the control node of the eighth transistor, a control node of the fifteenth transistor being coupled to the control node of the twelfth transistor.

According to an embodiment, the regulator comprises an eighteenth transistor coupled between the first node and the output node of the regulator.

According to an embodiment, the regulator comprises a nineteenth transistor, the nineteenth transistor being coupled in series between the twelfth and thirteenth transistors, a control node of the nineteenth transistor being coupled to the control node of the seventh transistor, a control node of the twelfth transistor being coupled to the junction point of the nineteenth and thirteenth transistors.

According to an embodiment, the regulator comprises a twentieth transistor, the twentieth transistor being coupled in series between the fifteenth and sixteenth transistors, a control node of the twentieth transistor being coupled to the control node of the nineteenth transistor.

According to an embodiment, a control node of the eighteenth transistor is coupled to the junction point of the twentieth and sixteenth transistors.

According to an embodiment, a control node of the thirteenth transistor is coupled to the junction point of the thirteenth and fourteenth transistors, a control node of the eighteenth transistor being coupled to the junction point of the fifteenth and sixteenth transistors.

According to an embodiment, the regulator comprises a first Miller capacitor, the first capacitor being coupled between the output node of the regulator and the junction point of the sixteenth and seventeenth transistors.

According to an embodiment, the regulator comprises a second Miller capacitor, the second capacitor being coupled between the output node of the regulator and the control node of the third transistor of the first branch.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 shows an example of an electronic device;

FIG. 2 shows an embodiment of a voltage regulator;

FIG. 3 shows another embodiment of a voltage regulator;

FIG. 4 shows another embodiment of a voltage regulator;

FIG. 5 shows another example of a voltage regulator;

FIG. 6 shows an example implementation of circuit 172 of FIG. 5; and

FIG. 7 shows another example of a voltage regulator.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

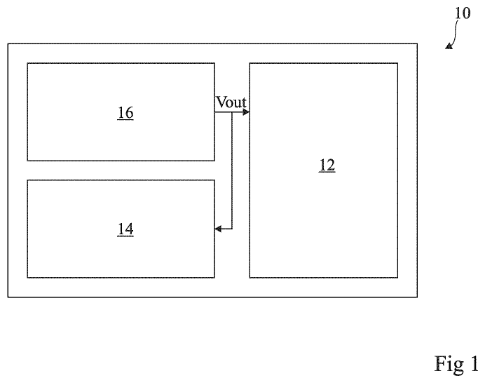

FIG. 1 shows an example of an electronic device 10. Device 10 is, for example, a chip.

Device 10 comprises, for example, an assembly 12 of circuits and components configured to allow the implementation of digital functions. Assembly 12 comprises, for example, one or a plurality of microcontrollers. Device 10 for example comprises a memory 14.

Device 10 comprises a power management unit 16. Unit 16 is for example configured to generate a power supply voltage Vout. Power supply voltage Vout is, for example, the power supply voltage of assembly 12 and/or of memory 14.

Unit 16 for example comprises at least one voltage regulator, or voltage follower, configured to hold voltage Vout at a desired value during the operation of device 10.

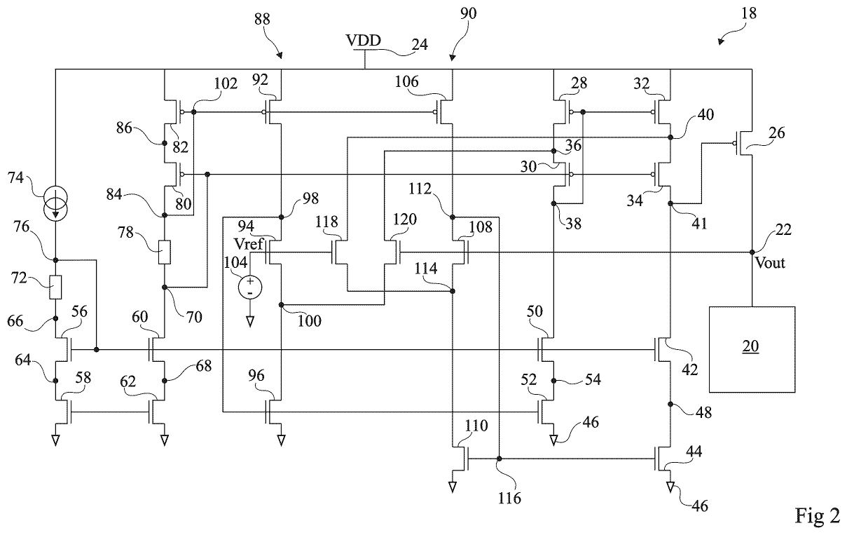

FIG. 2 shows an embodiment of a voltage regulator 18. Voltage regulator 18 is for example configured to be comprised in the power management unit 16 of FIG. 1.

Voltage regulator 18 is configured to power a load 20. Load 20 corresponds, for example, to the memory 14 or to the assembly 12 of FIG. 1. More precisely, regulator 18 comprises an output node 22 having power supply voltage Vout generated thereon. Load 20 is coupled, preferably connected, to node 22.

Regulator 18 comprises a transistor 26. Transistor 26 is, for example, an insulated-gate field-effect transistor (MOSFET-Metal Oxide Semiconductor Field Effect Transistor). Transistor 26 is preferably a P-channel transistor.

Node 22 is coupled to a node 24 of application of a power supply voltage VDD of device 10, that is, a power supply voltage of regulator 18, via transistor 26. In other words, a conduction node of transistor 26, for example the source, is coupled, preferably connected, to node 24 and another conduction node of transistor 26, for example the drain, is coupled, preferably connected, to node 22.

Regulator 18 also comprises transistors 28, 30, 32, 34. Transistors 28, 30, 32, 34 are, for example, metal-oxide semiconductor field-effect transistors (MOSFETs). Transistors 28, 30, 32, 34 are preferably P-channel transistors.

Transistors 28 and 30 are coupled in series. Similarly, transistors 32 and 34 are coupled in series. Transistors 28 and 30 are cascode-coupled. In other words, a conduction node of transistor 28, preferably the source, is coupled, preferably connected, to node 24. Another conduction node of transistor 28, for example the drain, is coupled, preferably connected, to a node 36. A conduction node of transistor 30, preferably the source, is coupled, preferably connected, to node 36. Another conduction node of transistor 30, for example the drain, is coupled, preferably connected, to a node 38. The control node of transistor 28, for example the gate, is coupled, preferably connected, to node 38.

Further, transistors 32 and 34 are coupled in a current mirror with transistors 28 and 30. In other words, a conduction node of transistor 32, preferably the source, is coupled, preferably connected, to node 24. Another conduction node of transistor 32, for example the drain, is coupled, preferably connected, to a node 40. A conduction node of transistor 34, preferably the source, is coupled, preferably connected, to node 40. Another conduction node of transistor 34, for example the drain, is coupled, preferably connected, to a node 41. The control node of transistor 32, for example the gate, is coupled, preferably connected, to the control node of transistor 28. Thus, the control node of transistor 32 is coupled, preferably connected, to node 38. The control node, for example the gate, of transistor 34 is coupled, preferably connected, to the control node of transistor 30.

The control node of transistor 26, for example the gate, is coupled, preferably connected, to node 41.

Regulator 18 further comprises transistors 42 and 44. Transistors 42 and 44 are, for example, metal-oxide semiconductor field effect transistors (MOSFETs). Transistors 42 and 44 are preferably N-channel transistors.

Transistors 42 and 44 are coupled in series. Transistors 42 and 44 are further coupled in series with transistors 32 and 34. In other words, a conduction node of transistor 44, preferably the source, is coupled, preferably connected, to a node 46 of application of a reference voltage, for example the ground. Another conduction node of transistor 44, for example the drain, is coupled, preferably connected, to a node 48. A conduction node of transistor 42, preferably the source, is coupled, preferably connected, to node 48. Another conduction node of transistor 42, for example the drain, is coupled, preferably connected, to node 41.

Similarly, regulator 18 further comprises transistors 50 and 52. Transistors 50 and 52 are, for example, metal-oxide semiconductor field effect transistors (MOSFETs). Transistors 50 and 52 are preferably N-channel transistors.

Transistors 50 and 52 are coupled in series. Transistors 50 and 52 are, further, coupled in series with transistors 28, 30. In other words, a conduction node of transistor 52, preferably the source, is coupled, preferably connected, to the node 46 of application of a reference voltage, for example, the ground. Another conduction node of transistor 52, for example the drain, is coupled, preferably connected, to a node 54. A conduction node of transistor 50, preferably the source, is coupled, preferably connected, to node 54. Another conduction node of transistor 50, for example the drain, is coupled, preferably connected, to node 38.

Regulator 18 further comprises transistors 56, 58, 60, 62. Transistors 56, 58, 60, 62 are, for example, metal-oxide semiconductor field effect transistors (MOSFETs). Transistors 56, 58, 60, 62 are preferably N-channel transistors.

Transistors 56, 58 are coupled in series. Transistors 60, 62 are also coupled in series. Transistors 56, 58 are cascode-coupled. In other words, a conduction node of transistor 58, preferably the source, is coupled, preferably connected, to node 46. Another conduction node of transistor 58, for example the drain, is coupled, preferably connected, to a node 64. A conduction node of transistor 56, preferably the source, is coupled, preferably connected, to node 64. Another conduction node of transistor 56, for example the drain, is coupled, preferably connected, to a node 66.

Further, transistors 60 and 62 are coupled in a current mirror with transistors 56, 58. In other words, a conduction node of transistor 62, preferably the source, is coupled, preferably connected, to node 46. Another conduction node of transistor 62, for example the drain, is coupled, preferably connected, to a node 68. A conduction node of transistor 60, preferably the source, is coupled, preferably connected, to node 68. Another conduction node of transistor 60, for example the drain, is coupled, preferably connected, to a node 70. The control node of transistor 62, for example the gate, is coupled, preferably connected, to the control node, for example the gate, of transistor 58. The control node, for example the gate, of transistor 60 is coupled, preferably connected, to the control node, for example the gate, of transistor 56. Further, the control node of transistor 60 is coupled, preferably connected, to the control node of transistor 50 and to the control node of transistor 42. In other words, the control nodes of transistors 42, 50, 56, 60 are coupled, preferably connected, together.

Regulator 18 further comprises a resistor 72 and a current source 74. Resistor 72 and source 74 are coupled in series. Resistor 72 and source 74 are coupled in series with transistors 56 and 58. In other words, a terminal of resistor 72 is coupled, preferably connected, to node 66 and another terminal of resistor 72 is coupled, preferably connected, to a node 76. Node 76 is further coupled, preferably connected, to the control node of transistor 56. Node 76 is thus coupled, preferably connected, to the control node of transistor 60. Source 74 comprises a terminal coupled, preferably connected, to node 76 and another terminal coupled, preferably connected, to node 24.

Regulator 18 comprises a resistor 78 and transistors 80 and 82. Transistors 80 and 82 are, for example, metal-oxide semiconductor field effect transistors (MOSFETs). Transistors 80 and 82 are preferably P-channel transistors.

Transistors 80, 82 and resistor 78 are coupled in series. Transistors 80, 82 and resistor 78 are coupled in series with transistors 60 and 62. In other words, a terminal of resistor 78 is coupled, preferably connected, to node 70 and another terminal of resistor 78 is coupled, preferably connected, to a node 84. A conduction node of transistor 80, preferably the source, is coupled, preferably connected, to node 24. Another conduction node of transistor 62, for example the drain, is coupled, preferably connected, to a node 86. A conduction node of transistor 80, preferably the source, is coupled, preferably connected, to node 86. Another conduction node of transistor 82, for example the drain, is coupled, preferably connected, to node 84. The control node of transistor 80 is coupled, preferably connected, to node 70.

Further, the control node of transistor 80 is coupled, preferably connected, to the control node of transistor 30 and to the control node of transistor 34. Thus, the control nodes of transistors 30, 34 and 80 are for example coupled, preferably connected, together. Further, the control node of transistor 82 is coupled, preferably connected, to node 84.

Regulator 18 further comprises two branches 88 and 92. Branches 88 and 90 both comprise three transistors coupled in series between nodes 24 and 46.

Thus, branch 88 comprises transistors 92, 94, 96. Transistors 92, 94, 96 are, for example, metal-oxide semiconductor field-effect transistors (MOSFETs). Transistors 94, 96 are preferably N-channel transistors. Transistor 92 is, for example, a P-channel transistor. Transistor 96 is, for example, a transistor identical to transistor 52. Alternatively, the surface area of transistor 96 is, for example, substantially equal to a multiple of the surface area of transistor 52.

Transistors 92, 94, 96 are coupled in series between nodes 24 and 46. In other words, transistor 92 comprises a conduction node, for example the source, coupled, preferably connected, to node 24. Another conduction node of transistor 92, for example the drain, is coupled, preferably connected, to a node 98. Transistor 94 comprises a conduction node, for example the source, coupled, preferably connected, to node 98. Another conduction node of transistor 94, for example the drain, is coupled, preferably connected, to a node 100. Transistor 96 comprises a conduction node, for example, the drain, coupled, preferably connected, to node 100. Another conduction node of transistor 96, for example, the source, is coupled, preferably connected, to node 46.

Transistor 92 comprises a control node, for example the gate, coupled, preferably connected, to a node 102. Node 102 is coupled, preferably connected, to the control node of transistor 82 and is coupled, preferably connected, to node 84. Transistor 94 comprises a control node, for example the gate, coupled, preferably connected, to a terminal, for example a positive terminal, of a voltage source 104. Voltage source 104 is configured to generate, on the positive terminal, a set point voltage Vref. Source 104 further comprises a terminal, for example a negative terminal, coupled, preferably connected, to node 46. Transistor 96 comprises a control node, for example the gate, coupled, preferably connected, to node 98, that is coupled, preferably connected, to the source of transistor 94, that is, coupled, preferably connected, to the junction point of transistors 92 and 94.

Similarly, branch 90 comprises transistors 106, 108, 110. Transistors 106, 108, 110 are, for example, metal-oxide semiconductor field-effect transistors (MOSFETs). Transistors 108, 110 are preferably N-channel transistors. Transistor 106 is, for example, a P-channel transistor. Transistor 110 is, for example, a transistor identical to transistor 44. Alternatively, the surface area of transistor 110 is, for example, substantially equal to a multiple of the surface area of transistor 44.

Transistors 106, 108, 110 are coupled in series between nodes 24 and 46. In other words, transistor 106 comprises a conduction node, for example the source, coupled, preferably connected, to node 24. Another conduction node of transistor 106, for example the drain, is coupled, preferably connected, to a node 112. Transistor 108 comprises a conduction node, for example the source, coupled, preferably connected, to node 112. Another conduction node of transistor 108, for example the drain, is coupled, preferably connected, to a node 114. Transistor 110 comprises a conduction node, for example the drain, coupled, preferably connected, to node 114. Another conduction node of transistor 110, for example the source, is coupled, preferably connected, to node 46.

Transistor 106 comprises a control node, for example the gate, coupled, preferably connected, to node 102. Node 102 is coupled, preferably connected, to the control nodes of transistors 82 and 92 and is coupled, preferably connected, to node 84. Transistor 108 comprises a control node, for example the gate, coupled, preferably connected, to the output node 22 having voltage Vout generated thereon. Transistor 110 comprises a control node, for example the gate, coupled, preferably connected, to a node 116, that is, coupled, preferably connected, to the source of transistor 108, that is, coupled, preferably connected, to the junction point of transistors 106 and 108. Node 116 is further coupled, preferably connected, to the control node of transistor 44.

Regulator 18 also comprises a pair of differential transistors 118, 120. Transistors 118, 120 are, for example, metal-oxide semiconductor field effect transistors (MOSFETs). Transistors 118, 120 are preferably N-channel transistors. Preferably, transistors 118 and 120 are identical transistors. Alternatively, one of transistors 118, 120 may have a surface area substantially equal to a multiple of the surface area of the other transistor among transistors 118, 120.

Transistor 118 is coupled between node 114, that is, the junction point of transistors 108 and 110, and node 40, that is, the junction point of transistors 32 and 34. In other words, a conduction node of transistor 118, for example the source, is coupled, preferably connected, to node 114. Another conduction node of transistor 118, for example the drain, is coupled, preferably connected, to node 40. A control node, for example the gate, of transistor 118 is coupled, preferably connected, to the control node of transistor 94 and to the positive terminal of source 104.

Transistor 120 is coupled between node 100, that is, the junction point of transistors 94 and 96, and node 36, that is, the junction point of transistors 28 and 36. In other words, a conduction node of transistor 120, for example, the source, is coupled, preferably connected, to node 100. Another conduction node of transistor 120, for example, the drain, is coupled, preferably connected, to node 36. A control node, for example the gate, of transistor 120 is coupled, preferably connected, to the control node of transistor 108 and to node 22.

When a current is drawn by the load, voltage Vout varies. This variation in voltage Vout causes a variation in the currents flowing through transistors 32, 34 and a variation in transistors 42, 44. The variation in voltage Vout does not only result in a variation in the currents flowing through transistors 32, 34, as in commonly-used regulators. The current at node 41, that is, the control current of transistor 26, thus varies more rapidly in regulator 18, resulting in a faster regulation of voltage Vout.

The bias applied to the transistors 118 and 120 of the differential pair is thus dynamic.

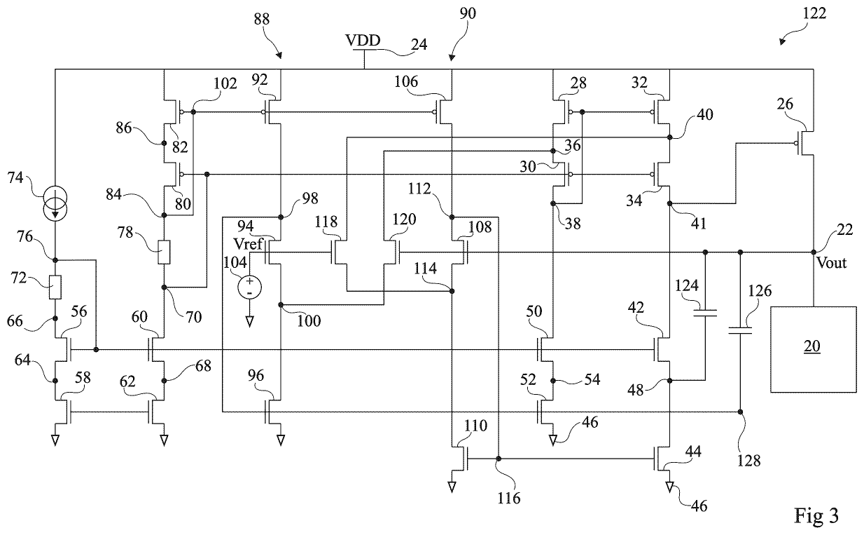

FIG. 3 shows another embodiment of a voltage regulator 122.

Regulator 122 comprises the components of the regulator 18 of FIG. 2, arranged in identical fashion. These different components, that is, transistors 26, 32, 34, 42, 28, 30, 50, 52, 106, 108, 110, 18, 120, 92, 94, 96, 82, 80, 60, 62, 56, 58, resistors 72 and 78, and sources 74 and 104, are thus present in regulator 122 and will not be described again in detail.

Regulator 122 further comprises capacitors 124 and 126. Capacitors 124 and 126 are Miller capacitors, and thus compensate for the gain of the loop and to accelerate the response of the regulator.

Capacitor 124 is coupled between output node 22 and node 48, that is, the junction node of transistors 42 and 44. In other words, a terminal of capacitor 124 is coupled, preferably connected, to node 22 and another terminal of capacitor 124 is coupled, preferably connected, to node 48.

Capacitor 126 is connected between output node 22 and a node 128. In other words, a terminal of capacitor 126 is coupled, preferably connected, to node 22 and another terminal of capacitor 126 is coupled, preferably connected, to node 128. Node 128 is also coupled, preferably connected, to the control nodes of transistors 52 and 96.

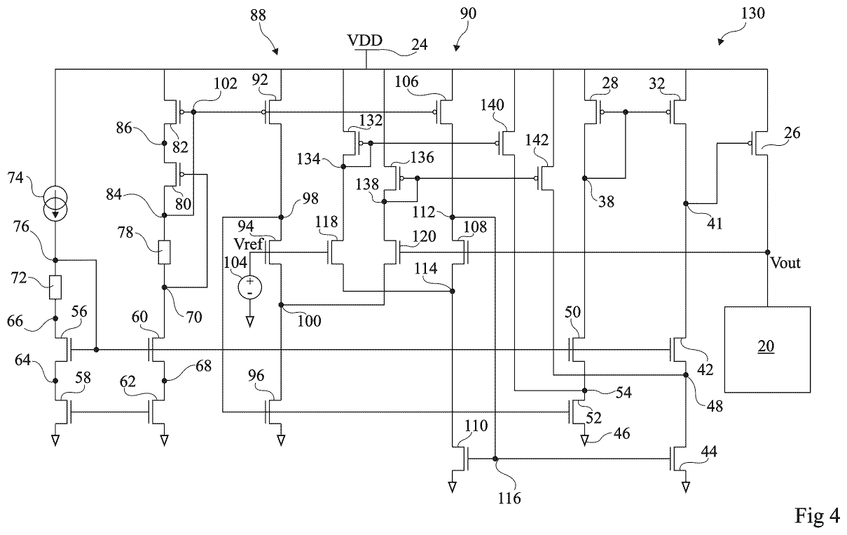

FIG. 4 shows another embodiment of a voltage regulator 130.

Regulator 130 comprises the components of the regulator 18 of FIG. 2, arranged in identical fashion, except for transistors 30 and 34. These different components, that is, transistors 26, 32, 42, 28, 50, 52, 106, 108, 110, 18, 120, 92, 94, 96, 82, 80, 60, 62, 56, 58, resistors 72, and 78, and sources 74 and 104, are thus present in regulator 122 and will not be described again in detail. In the absence of transistors 30 and 34, a conduction node of transistor 28, for example, the drain, is coupled, preferably connected, to node 38 and a conduction node of transistor 32, for example, the drain, is coupled, preferably connected, to node 41. Thus, the control node of transistor 28 is coupled, preferably connected, to the drain of transistor 28. Additionally, the control node of transistor 26 is coupled, preferably connected, to the drain of transistor 32.

Conversely to regulator 18, transistor 118 is not coupled between node 40 and node 114. Similarly, transistor 120 is not coupled between node 36 and node 100. Transistor 118 is coupled in series with a transistor 132, different from transistor 32, between nodes 114 and 24. Similarly, transistor 120 is coupled in series with a transistor 136, different from transistor 28, between nodes 100 and 24.

Transistors 132 and 136 are, for example, metal-oxide semiconductor field-effect transistors (MOSFETs). Transistors 132 and 136 are preferably P-channel transistors.

In other words, a conduction node, for example the source, of transistor 118 is, as in FIG. 2, coupled, preferably connected, to node 114 and another conduction node of transistor 118 is coupled, preferably connected, to a node 134. A conduction node of transistor 132, for example the source, is coupled, preferably connected, to node 24 and another conduction node of transistor 132, for example the drain, is coupled, preferably connected, to node 134. The control node of transistor 132, for example the gate, is coupled, preferably connected, to node 134.

Further, a conduction node, for example the source, of transistor 120 is, as in FIG. 2, coupled, preferably connected, to node 100 and another conduction node of transistor 120 is coupled, preferably connected, to a node 138. A conduction node of transistor 136, for example the source, is coupled, preferably connected, to node 24 and another conduction node of transistor 136, for example the drain, is coupled, preferably connected, to node 138. The control node of transistor 136, for example the gate, is coupled, preferably connected, to node 138.

Regulator 130 further comprises transistors 140 and 142. Transistors 140 and 142 are, for example, metal-oxide semiconductor field effect transistors (MOSFETs). Transistors 140 and 142 are preferably P-channel transistors.

Transistor 140 is coupled between node 24 and node 54. In other words, a conduction node of transistor 140, for example the source, is coupled, preferably connected, to node 24 and another conduction node of transistor 140, for example the drain, is coupled, preferably connected, to node 54.

Similarly, transistor 142 is coupled between node 24 and node 48. In other words, a conduction node of transistor 142, for example the source, is coupled, preferably connected, to node 24 and another conduction node of transistor 142, for example the drain, is coupled, preferably connected, to node 48.

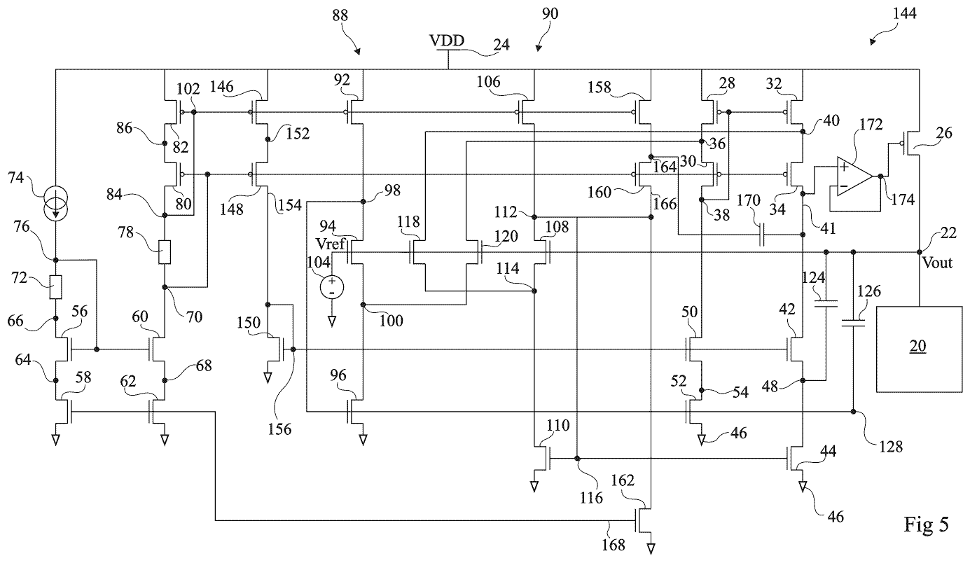

FIG. 5 shows another example of a voltage regulator 144.

The regulator 144 comprises the components of the regulator 122 shown in FIG. 3, arranged in identical fashion. These various components, i.e. transistors 26, 28, 30, 32, 34, 42, 44, 50, 52, 56, 58, 60, 62, 80, 82, 92, 94, 96, 106, 108, 110, 118, 120, resistors 72 and 78, capacitors 124, 126 and sources 74 and 104, are thus present in regulator 144 and will not be described again in detail. The regulator 144 differs from the regulator 122 of FIG. 3 in that the control node of transistor 60 is not, as in FIG. 3, coupled to the control nodes of transistors 42 and 50.

The regulator 144 comprises transistors 146, 148, 150. Transistors 146, 148, 150 are, for example, insulated gate field effect transistors (MOSFETs). Transistors 146, 148 are preferably P-channel transistors. Transistor 150 is, for example, an N-channel transistor.

Transistors 146, 148, 150 are coupled in series between nodes 24 and 46. In other words, transistor 146 comprises a conduction node, for example the source, coupled, preferably connected, to node 24. Another conduction node of transistor 146, for example the drain, is coupled, preferably connected, to a node 152. Transistor 148 comprises a conduction node, for example the source, coupled, preferably connected, to node 152. Another conduction node of transistor 148, for example the drain, is coupled, preferably connected, to node 154. Transistor 150 comprises a conduction node, for example the drain, coupled, preferably connected, to node 154. Another conduction node of transistor 150, for example the source, is coupled, preferably connected, to node 46.

Transistor 146 comprises a control node, for example the gate, coupled, preferably connected, to node 102. Node 102 is coupled, preferably connected, to the control nodes of transistors 82, 92 and 106 and is coupled, preferably connected, to node 84. Transistor 148 comprises a control node, for example the gate, coupled, preferably connected, to node 70. Node 70 is coupled, preferably connected, to the control nodes of transistors 80, 30 and 34. Transistor 150 comprises a control node, for example the gate, coupled, preferably connected, to node 156. Node 156 is coupled, preferably connected, to the control node of transistors 42 and 50. Node 156 is further coupled, preferably connected, to node 154.

The regulator 144 comprises transistors 158, 160, 162. Transistors 158, 160, 162 are, for example, insulated gate field effect transistors (MOSFETs). Transistors 158, 160 are preferably P-channel transistors. Transistor 162 is, for example, an N-channel transistor.

Transistors 158, 160, 162 are coupled in series between nodes 24 and 46. In other words, transistor 158 comprises a conduction node, for example the source, coupled, preferably connected, to node 24. Another conduction node of transistor 158, for example the drain, is coupled, preferably connected, to node 164. Transistor 160 comprises a conduction node, for example the source, coupled, preferably connected, to node 164. Another conduction node of transistor 160, for example the drain, is coupled, preferably connected, to node 166. Transistor 162 comprises a conduction node, for example the drain, coupled, preferably connected, to node 166. Another conduction node of transistor 162, for example the source, is coupled, preferably connected, to node 46.

Transistor 158 comprises a control node, for example the gate, coupled, preferably connected, to node 102. Node 102 is coupled, preferably connected, to the control nodes of transistors 82, 92, 106 and 146 and is coupled, preferably connected, to node 84. Transistor 160 comprises a control node, for example the gate, coupled, preferably connected, to node 70. Node 70 is coupled, preferably connected, to the control nodes of transistors 80, 30, 34 and 148. Transistor 162 comprises a control node, for example the gate, coupled, preferably connected, to node 168. Node 168 is coupled, preferably connected, to the control node of transistors 58 and 62.

The regulator 144 also includes a capacitor 170. Capacitor 170 is coupled between node 41 and node 1644. Thus, one terminal of capacitor 170 is coupled, preferably connected, to node 41, i.e. the midpoint of transistors 34 and 42, and another terminal of capacitor 170 is coupled, preferably connected, to node 164, i.e. the midpoint of transistors 158 and 160.

The regulator 144 also includes a buffer circuit 172. In the example shown in FIG. 5, circuit 172 is an operational amplifier.

Circuit 172 comprises a first input, for example the non-inverting (+) input, and a second input, for example the inverting (−) input. The first input is coupled, preferably connected, to node 41. The second input is coupled, preferably connected, to a node 174.

Circuit 172 includes an output. Said output is coupled, preferably connected, to node 174. Node 174 is further coupled, preferably connected, to the control node of transistor 26. Thus, the second input and output of circuit 172 are coupled, preferably connected, to the control node of transistor 26.

Capacitor 170 improves regulator stability. Specifically, capacitor 170 reduces the frequency of branch 90 and prevents overvoltage. Circuit 172 provides a very fast load transient response.

In another embodiment, regulator 144 may comprise a resistor, not shown, coupled in series with capacitor 170 between nodes 41 and 164.

Transistors 158, 160, 162 permit the retention of a fast line transient response.

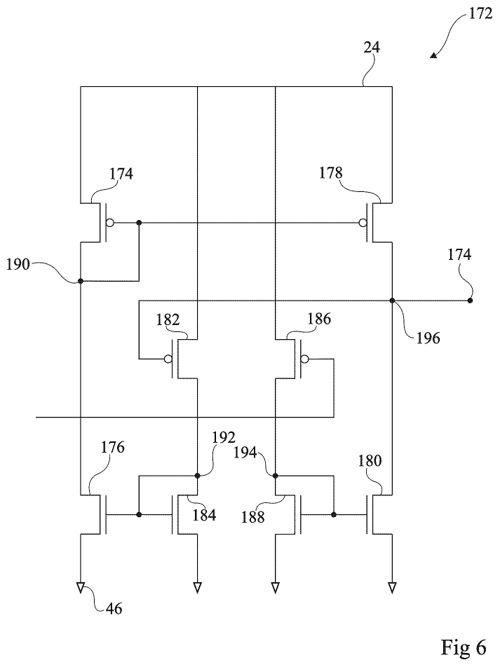

FIG. 6 shows a variant of part of the embodiment shown in FIG. 5. Specifically, FIG. 6 illustrates an example implementation of circuit 172.

Circuit 172 comprises transistors 174, 176, 178, 180, 182, 184, 186, 188. The transistors 174, 176, 178, 180, 182, 184, 186, 188 are, for example, insulated gate field effect transistors (MOSFETs). Transistors 174, 178, 182, 186 are preferably P-channel transistors. Transistors 176, 180, 184, 188 are, for example, N-channel transistors.

Transistors 174 and 176 are coupled in series between nodes 24 and 46. In other words, transistor 174 comprises a conduction node, for example the source, coupled, preferably connected, to node 24. Another conduction node of transistor 174, for example the drain, is coupled, preferably connected, to node 190. Transistor 176 comprises a conduction node, for example the source, coupled, preferably connected, to node 190. Another conduction node of transistor 176, for example the drain, is coupled, preferably connected, to node 46.

Similarly, transistors 182 and 184 are coupled in series between nodes 24 and 46. In other words, transistor 182 comprises a conduction node, for example the source, coupled, preferably connected, to node 24. Another conduction node of transistor 182, for example the drain, is coupled, preferably connected, to node 192. Transistor 184 comprises a conduction node, for example the source, coupled, preferably connected, to node 192. Another conduction node of transistor 184, for example the drain, is coupled, preferably connected, to node 46.

Similarly, transistors 186 and 188 are coupled in series between nodes 24 and 46. In other words, transistor 186 comprises a conduction node, for example the source, coupled, preferably connected, to node 24. Another conduction node of transistor 186, for example the drain, is coupled, preferably connected, to node 194. Transistor 188 comprises a conduction node, for example the source, coupled, preferably connected, to node 194. Another conduction node of transistor 188, for example the drain, is coupled, preferably connected, to node 46.

Similarly, transistors 178 and 180 are coupled in series between nodes 24 and 46. In other words, transistor 178 comprises a conduction node, for example the source, coupled, preferably connected, to node 24. Another conduction node of transistor 178, for example the drain, is coupled, preferably connected, to node 196. Transistor 180 comprises a conduction node, for example the source, coupled, preferably connected, to node 196. Another conduction node of transistor 180, for example the drain, is coupled, preferably connected, to node 46.

Transistor 174 comprises a control node, for example the gate, coupled, preferably connected, to node 190. Node 190 is further coupled, preferably connected, to the control node of transistor 178. Transistor 176 comprises a control node, for example the gate, coupled, preferably connected, to node 192. Node 192 is further coupled, preferably connected, to the control node of transistor 184. Transistor 182 comprises a control node, for example the gate, coupled, preferably connected, to node 196. Node 196 is further coupled, preferably connected, to node 174 and thus to the output of circuit 172. Node 196 is also coupled to the inverting input of circuit 172. Transistor 180 comprises a control node, for example the gate, coupled, preferably connected, to node 194. Node 194 is further coupled, preferably connected, to the control node of transistor 188. Transistor 186 comprises a control node, for example the gate, coupled, preferably connected, to the non-inverting input of circuit 172 and thus to node 41.

The circuit 172 described in relation to FIG. 6 ensures an adaptive bias in the load current. It also improves transient response as the load current increases.

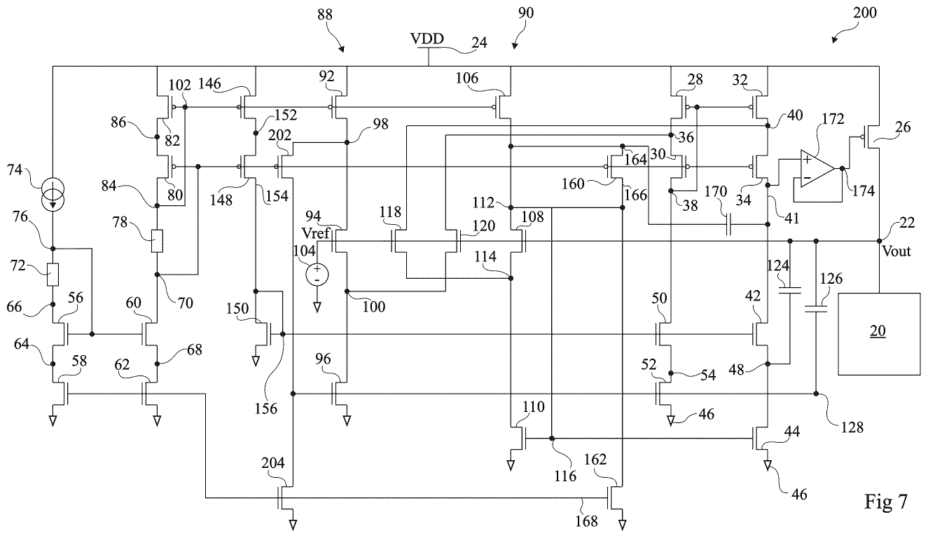

FIG. 7 shows another example of a voltage regulator 200.

The regulator 200 comprises the components of the regulator 144 shown in FIG. 5, arranged in identical fashion. These various components, i.e. transistors 26, 28, 30, 32, 34, 42, 44, 50, 52, 56, 58, 60, 62, 80, 82, 92, 94, 96, 106, 108, 110, 118, 120, 146, 148, 150, 160, 162, resistors 72 and 78, circuit 172, capacitors 124, 126, 170 and sources 74 and 104, are thus present in the regulator 122 and will not be described again in detail.

Regulator 200 differs from regulator 144 in that regulator 200 does not include transistor 158. Node 164 is then coupled, preferably connected, to node 112, i.e. the midpoint of transistors 106 and 108.

The regulator 144 comprises transistors 202 and 204. Transistors 202 and 204 are, for example, insulated gate field effect transistors (MOSFETs). Transistor 202 is preferably a P-channel transistor. Transistor 204 is, for example, an N-channel transistor.

Transistors 202 and 204 are coupled in series with transistor 92 between nodes 24 and 46. In other words, transistor 92 comprises a conduction node, for example the source, coupled, preferably connected, to node 24. Another conduction node of transistor 92, for example the drain, is coupled, preferably connected, to node 98. Transistor 202 comprises a conduction node, for example the source, coupled, preferably connected, to node 98. Another conduction node of transistor 202, for example the drain, is coupled, preferably connected, to node 128, and thus to the control nodes of transistors 96 and 52. Transistor 204 comprises a conduction node, for example the drain, coupled, preferably connected, to node 128. Another conduction node of transistor 204, for example the source, is coupled, preferably connected, to node 46.

Transistor 202 comprises a control node, e.g. the gate, coupled, preferably connected, to node 70. Node 70 is coupled, preferably connected, to the control nodes of transistors 80, 148, 160, 30 and 34. Transistor 204 comprises a control node, for example the gate, coupled, preferably connected, to node 168. Node 168 is coupled, preferably connected, to the control node of transistors 62, 64, 162.

The addition of transistors 2020 and 204 equalizes the drain voltages of the differential pairs, i.e. transistors 94 and 118 and transistors 120 and 108.

For example, circuit 172 is implemented as described in relation to FIG. 6.

An advantage of described embodiments is that they apply a variable bias to the two conduction terminals of the transistors of the differential pair. Thus, the response of the current regulator is faster in case of a variation on the output node.

Various embodiments and variants have been described. Those skilled in the art will understand that certain features of these various embodiments and variants may be combined, and other variants will occur to those skilled in the art. In particular, Miller capacitors 124 and 126 may be present, arranged at the same locations as in the embodiment of FIG. 3, in the embodiment of FIG. 4.

Finally, the practical implementation of the described embodiments and variants is within the abilities of those skilled in the art based on the functional indications given hereabove.

What is claimed is:

1. A device comprising:
a voltage regulator comprising:
first and second branches, each first and second branch comprising, in order, first, second, and third transistors coupled in series, between a first node of application of a power supply voltage and a second node of application of a reference voltage, control nodes of the first transistors of the first and second branches being coupled together, a control node of the third transistor of each first and second branch being coupled to a junction point of the first and second transistors of the respective branch;
a fourth transistor coupled between a junction point of the second and third transistors of the second branch and a third node, control nodes of the fourth transistor and of the second transistor of the first branch being coupled together to a node of application of a set point voltage; and
a fifth transistor coupled between a junction point of the second and third transistors of the first branch and a fourth node, control nodes of the fifth transistor and of the second transistor of the second branch being coupled together to an output node of the regulator;
a microcontroller having a first power supply input coupled to the output node of the regulator; and
a memory having a second power supply input coupled to the output node of the regulator.

2. The device according to claim 1, wherein the first transistors of the first and second branches are P-channel metal oxide semiconductor field effect transistor (MOSFET) transistors, and the second and third transistors of the first and second branches are N-channel MOSFET transistors.

3. The device according to claim 1, wherein the regulator comprises, coupled in order in series between the first and second nodes, sixth and seventh transistors, a first resistor, and eighth and ninth transistors, a control node of the sixth transistor being coupled to a junction point of the seventh transistor and of the first resistor, a control node of the sixth transistor being further coupled to the control nodes of the first transistors of the first and second branches, a control node of the seventh transistor being coupled to a junction point of the eighth transistor and of the first resistor.

4. The device according to claim 3, wherein the regulator comprises, coupled in order in series between the first and second nodes, a current source, a second resistor, and tenth and eleventh transistors, a control node of the tenth transistor being coupled to a junction point of the second resistor and of the current source and to a control node of the eighth transistor, a control node of the eleventh transistor being coupled to a control node of the ninth transistor.

5. The device according to claim 3, wherein the regulator comprises twelfth, thirteenth, and fourteenth transistors coupled, in order, in series between the first and second nodes, a control node of the fourteenth transistor being coupled to the control node of the third transistor of the first branch, a control node of the thirteenth transistor being coupled to a control node of the eighth transistor.

6. The device according to claim 5, wherein the regulator comprises fifteenth, sixteenth, and seventeenth transistors coupled, in order, in series between the first and second nodes, a control node of the seventeenth transistor being coupled to the control node of the third transistor of the second branch, a control node of the sixteenth transistor being coupled to the control node of the eighth transistor, a control node of the fifteenth transistor being coupled to a control node of the twelfth transistor.

7. The device according to claim 6, wherein a control node of the sixteenth transistor is coupled to the control node of the eighth transistor, a control node of the thirteenth transistor being coupled to the control node of the eighth transistor.

8. The device according to claim 6, wherein the regulator comprises an eighteenth transistor coupled between the first node and the output node of the regulator.

9. The device according to claim 8, wherein the regulator comprises a nineteenth transistor, the nineteenth transistor being coupled in series between the twelfth and thirteenth transistors, a control node of the nineteenth transistor being coupled to the control node of the seventh transistor, a control node of the twelfth transistor being coupled to a junction point of the nineteenth and thirteenth transistors.

10. The device according to claim 9, wherein the regulator comprises a twentieth transistor, the twentieth transistor being coupled in series between the fifteenth and sixteenth transistors, a control node of the twentieth transistor being coupled to the control node of the nineteenth transistor.

11. The device according to claim 10, wherein the device comprises twenty-first, twenty-second and twenty-third transistors coupled, in order, in series between the first and second nodes, a control node of the twenty-first transistor being coupled to the control node of the sixth transistor, a control node of the twenty-second transistor being coupled to the control node of the seventh transistor, a control node of the twenty-third transistor being coupled to the control node of the thirteenth transistor, the control node of the twenty-third transistor being further coupled to a midpoint between the twenty-second transistor and the twenty-third transistor, the device comprising twenty-fourth, twenty-fifth and twenty-sixth transistors coupled, in order, in series between the first and second nodes, a control node of the twenty-fourth transistor being coupled to the control node of the sixth transistor, a control node of the twenty-fifth transistor being coupled to the control node of the seventh transistor, a control node of the twenty-sixth transistor being coupled to the control node of the ninth transistor, the device further comprising a third capacitor coupled between a midpoint of the twenty-fourth and twenty-fifth transistors and a midpoint of the twentieth and sixteenth transistors.

12. The device according to claim 10, wherein the device comprises twenty-first, twenty-second and twenty-third transistors coupled, in that order, in series between first and second nodes, a control node of the twenty-first transistor being coupled to the control node of the sixth transistor, a control node of the twenty-second transistor being coupled to the control node of the seventh transistor, a control node of the twenty-third transistor being coupled to the control node of the thirteenth transistor, the control node of the twenty-third transistor being further coupled to a midpoint between the twenty-second transistor and the twenty-third transistor, the device comprising coupled twenty-fifth and twenty-sixth transistors, in order, in series between a midpoint of the first and second transistors of the second branch and the second node, a control node of the twenty-fifth transistor being coupled to the control node of the seventh transistor, a control node of the twenty-sixth transistor being coupled to the control node of the ninth transistor, a midpoint of the twenty-fifth and twenty-sixth transistors being coupled to the midpoint of the first and second transistors of the second branch, the device comprising twenty-seventh and twenty-eighth transistors coupled, in order, in series between the midpoint of the first and second transistors of the first branch and the second node, a control node of the twenty-seventh transistor being coupled to the control node of the seventh transistor, a control node of the twenty-eighth transistor being coupled to the control node of the ninth transistor, a midpoint of the twenty-seventh and twenty-eighth transistors being coupled to the control node of the third transistor of the first branch, the device further comprising a third capacitor coupled between the midpoint of the first and second transistors and a midpoint of the twentieth and sixteenth transistors.

13. The device according to claim 1, wherein the regulator comprises an eighteenth transistor coupled between the first node and the output node of the regulator.

14. The device according to claim 10, wherein a control node of the eighteenth transistor is coupled to a junction point of the twentieth and sixteenth transistors.

15. The device according to claim 8, wherein a control node of the thirteenth transistor is coupled to a junction point of the thirteenth and fourteenth transistors, a control node of the eighteenth transistor being coupled to a junction point of the fifteenth and sixteenth transistors.

16. The device according to claim 10, wherein the regulator comprises a first Miller capacitor, the first Miller capacitor being coupled between the output node of the regulator and a junction point of the sixteenth and seventeenth transistors.

17. The device according to claim 16, wherein the regulator comprises a second Miller capacitor, the second Miller capacitor being coupled between the output node of the regulator and the control node of the third transistor of the first branch.

18. The device according to claim 17, wherein a control node of the eighteenth transistor being coupled to a midpoint of the twentieth and sixteenth transistors by an operational amplifier, a non-inverting input of the operational amplifier being coupled to the midpoint of the twentieth and sixteenth transistors, an inverting input of the operational amplifier being coupled to an output of the operational amplifier, the output of the operational amplifier being further coupled to the control node of the eighteenth transistor.

19. A voltage regulator comprising:
first and second branches, each first and second branch comprising, in order, first, second, and third transistors coupled in series, between a first node of application of a power supply voltage and a second node of application of a reference voltage, control nodes of the first transistors of the first and second branches being coupled together, a control node of the third transistor of each first and second branch being coupled to a junction point of the first and second transistors of the respective branch;
a fourth transistor coupled between a junction point of the second and third transistors of the second branch and a third node, control nodes of the fourth transistor and of the second transistor of the first branch being coupled together to a node of application of a set point voltage; and
a fifth transistor coupled between a junction point of the second and third transistors of the first branch and a fourth node, control nodes of the fifth transistor and of the second transistor of the second branch being coupled together to an output node of the regulator.

20. The voltage regulator according to claim 19, wherein the regulator comprises, coupled in order in series between the first and second nodes, sixth and seventh transistors, a first resistor, and eighth and ninth transistors, a control node of the sixth transistor being coupled to a junction point of the seventh transistor and of the first resistor, a control node of the sixth transistor being further coupled to the control nodes of the first transistors of the first and second branches, a control node of the seventh transistor being coupled to a junction point of the eighth transistor and of the first resistor.

21. The voltage regulator according to claim 20, wherein the regulator comprises, coupled in order in series between the first and second nodes, a current source, a second resistor, and tenth and eleventh transistors, a control node of the tenth transistor being coupled to a junction point of the second resistor and of the current source and to a control node of the eighth transistor, a control node of the eleventh transistor being coupled to a control node of the ninth transistor.

22. The voltage regulator according to claim 20, wherein the regulator comprises twelfth, thirteenth, and fourteenth transistors coupled, in order, in series between the first and second nodes, a control node of the fourteenth transistor being coupled to the control node of the third transistor of the first branch, a control node of the thirteenth transistor being coupled to a control node of the eighth transistor.

23. The voltage regulator according to claim 22, wherein the regulator comprises fifteenth, sixteenth, and seventeenth transistors coupled, in order, in series between the first and second nodes, a control node of the seventeenth transistor being coupled to the control node of the third transistor of the second branch, a control node of the sixteenth transistor being coupled to the control node of the eighth transistor, a control node of the fifteenth transistor being coupled to a control node of the twelfth transistor.

24. The voltage regulator according to claim 23, wherein a control node of the sixteenth transistor is coupled to the control node of the eighth transistor, a control node of the thirteenth transistor being coupled to the control node of the eighth transistor.

25. The voltage regulator according to claim 23, wherein the regulator comprises an eighteenth transistor coupled between the first node and the output node of the regulator.

26. The voltage regulator according to claim 25, wherein the regulator comprises a nineteenth transistor, the nineteenth transistor being coupled in series between the twelfth and thirteenth transistors, a control node of the nineteenth transistor being coupled to the control node of the seventh transistor, a control node of the twelfth transistor being coupled to a junction point of the nineteenth and thirteenth transistors.

27. The voltage regulator according to claim 26, wherein the regulator comprises a twentieth transistor, the twentieth transistor being coupled in series between the fifteenth and sixteenth transistors, a control node of the twentieth transistor being coupled to the control node of the nineteenth transistor.

28. The voltage regulator according to claim 27, wherein the voltage regulator comprises twenty-first, twenty-second and twenty-third transistors coupled, in order, in series between the first and second nodes, a control node of the twenty-first transistor being coupled to the control node of the sixth transistor, a control node of the twenty-second transistor being coupled to the control node of the seventh transistor, a control node of the twenty-third transistor being coupled to the control node of the thirteenth transistor, the control node of the twenty-third transistor being further coupled to a midpoint between the twenty-second transistor and the twenty-third transistor, the voltage regulator comprising twenty-fourth, twenty-fifth and twenty-sixth transistors coupled, in order, in series between the first and second nodes, a control node of the twenty-fourth transistor being coupled to the control node of the sixth transistor, a control node of the twenty-fifth transistor being coupled to the control node of the seventh transistor, a control node of the twenty-sixth transistor being coupled to the control node of the ninth transistor, the voltage regulator further comprising a third capacitor coupled between a midpoint of the twenty-fourth and twenty-fifth transistors and a midpoint of the twentieth and sixteenth transistors.

29. The voltage regulator according to claim 27, wherein the voltage regulator comprises twenty-first, twenty-second and twenty-third transistors coupled, in that order, in series between first and second nodes, a control node of the twenty-first transistor being coupled to the control node of the sixth transistor, a control node of the twenty-second transistor being coupled to the control node of the seventh transistor, a control node of the twenty-third transistor being coupled to the control node of the thirteenth transistor, the control node of the twenty-third transistor being further coupled to a midpoint between the twenty-second transistor and the twenty-third transistor, the voltage regulator comprising coupled twenty-fifth and twenty-sixth transistors, in order, in series between a midpoint of the first and second transistors of the second branch and the second node, a control node of the twenty-fifth transistor being coupled to the control node of the seventh transistor, a control node of the twenty-sixth transistor being coupled to the control node of the ninth transistor, a midpoint of the twenty-fifth and twenty-sixth transistors being coupled to the midpoint of the first and second transistors of the second branch, the voltage regulator comprising twenty-seventh and twenty-eighth transistors coupled, in order, in series between the midpoint of the first and second transistors of the first branch and the second node, a control node of the twenty-seventh transistor being coupled to the control node of the seventh transistor, a control node of the twenty-eighth transistor being coupled to the control node of the ninth transistor, a midpoint of the twenty-seventh and twenty-eighth transistors being coupled to the control node of the third transistor of the first branch, the voltage regulator further comprising a third capacitor coupled between the midpoint of the first and second transistors and a midpoint of the twentieth and sixteenth transistors.

30. The voltage regulator according to claim 27, wherein a control node of the thirteenth transistor is coupled to a junction point of the thirteenth and fourteenth transistors, a control node of the eighteenth transistor being coupled to a junction point of the fifteenth and sixteenth transistors.

31. The voltage regulator according to claim 27, wherein the regulator comprises:
a first Miller capacitor, the first Miller capacitor being coupled between the output node of the regulator and a junction point of the sixteenth and seventeenth transistors; and
a second Miller capacitor, the second Miller capacitor being coupled between the output node of the regulator and the control node of the third transistor of the first branch.

32. The voltage regulator according to claim 31, wherein a control node of the eighteenth transistor being coupled to a midpoint of the twentieth and sixteenth transistors by an operational amplifier, a non-inverting input of the operational amplifier being coupled to the midpoint of the twentieth and sixteenth transistors, an inverting input of the operational amplifier being coupled to an output of the operational amplifier, the output of the operational amplifier being further coupled to the control node of the eighteenth transistor.
